(19) United States
(12) Patent Application Publication
(10) Pub. No.: US 2025/0112186 A1
(43) Pub. Date: Apr. 3, 2025

(54) TILT MITIGATION IN SELF-ALIGNMENT ASSISTED ASSEMBLY OF IC DIE

(71) Applicant: Intel Corporation, Santa Clara, CA (US)

(72) Inventors: Feras Eid, Chandler, AZ (US); Adel Elsherbini, Chandler, AZ (US); Thomas Sounart, Chandler, AZ (US); Kimin Jun, Portland, OR (US); Wenhao Li, Chandler, AZ (US)

(73) Assignee: Intel Corporation, Santa Clara, CA (US)

(21) Appl. No.: 18/374,574

(22) Filed: Sep. 28, 2023

(51) Int. Cl. H01L 23/00

(52) U.S. Cl. CPC H01L 24/08; H01L 24/80; H01L 2224/08225; H01L 2224/80143; H01L 2224/80895; H01L 2224/80896

(57) ABSTRACT

A surface of at least one of an integrated circuit (IC) die structure or a substrate structure to which the IC die structure is to be bonded include a biphilic region suitable for liquid droplet confinement and droplet-based fine alignment of the IC die structure to the substrate structure. A biphilic region may include an inner region surrounded by bonding regions, or between an adjacent pair of bonding regions. The inner region may improve fine alignment, particularly if there is a significant amount of tilt between a bonding surface of the IC die structure and a bonding surface of the substrate structure during placement. The inner region may, for example, facilitate the confinement of two or more droplets on the bonding regions. Inner or outer regions of a biphilic structure may be segmented or contiguous and intersecting IC die edges may also be non-orthogonal.

### BACKGROUND

Integrated circuit (IC) die can be assembled with solder attachment techniques where solder features are brought into contact to join dies to a host or base substrate structure. However, solder assembly techniques are difficult to scale below solder-bonded feature pitches that are in the tens of microns (e.g., 10-25 μm).

IC die may instead be assembled with hybrid bonding techniques where metallic bond sites of an IC die are directly interdiffused with corresponding metallic bond sites of a host or base substrate structure. Such bonding is referred to as “hybrid” because a bond also forms between dielectric materials adjacent to the metallic bond sites. During a hybrid bonding process, components (e.g., dies) having corresponding bond sites, are brought together to interface with one another. At room temperature, dielectric material adheres sufficiently to establish an initial bond (e.g., due to Van der Waals forces). A thermal anneal may then fuse complementary metallic bond sites, and also increase the strength of the dielectric material bond interface. Hybrid bonding techniques are scalable well below bonded feature pitches of 1 μm. However, such nanometer pitch assembly techniques rely on nanometer scale (e.g., <500 nm) fine alignment of IC die to the base substrate structure, which can be time consuming and/or expensive to implement.

Techniques and architectures for hybrid bonding at nanometer scales in high volume manufacturing are therefore commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating self-alignment assisted assembly (SA3) methods for integrated circuit (IC) die structures, in accordance with some embodiments;

FIG. 2A is a cross-sectional view of a wafer or panel comprising a plurality of base substrate structures, each base substrate structure comprising a biphilic structure with an inner region dividing IC die bonding regions, in accordance with some embodiments;

FIG. 2B is a plan view of the base wafer or panel illustrated in FIG. 2A, in accordance with some embodiments;

FIG. 3A is a cross-sectional view of an IC die structure comprising one or more biphilic structures within IC die bonding regions, in accordance with some embodiments;

FIG. 3B is a plan view of the IC die structure illustrated in FIG. 3A, in accordance with some embodiments;

FIG. 4A is a cross-sectional view of a plurality of liquid droplets on IC die bonding regions of a base substrate structure, in accordance with some embodiments;

FIG. 4B is a plan view of the plurality of liquid droplets on the base substrate structure illustrated in FIG. 3A, in accordance with some embodiments;

FIG. 5A is a cross-sectional view of an IC die structure being coarse aligned and placed upon a plurality of liquid droplets, in accordance with some embodiments;

FIG. 5B is a plan view of alignment and placement of the IC die structure illustrated in FIG. 5A, in accordance with some embodiments;

FIG. 6A is a cross-sectional view of a composite structure comprising an IC die structure hybrid bonded to bonding regions of a base substrate structure, in accordance with some embodiments;

FIG. 6B is a plan view of the composite structure shown in FIG. 6A, in accordance with some embodiments;

FIG. 7 is a plan view of liquid droplets on bonding regions of a base substrate structure, in accordance with some alternative embodiments;

FIG. 8 is a plan view of bonding regions on an IC die structure, in accordance with some alternative embodiments;

FIG. 9 is a plan view of a bonding regions on an IC die structure, in accordance with some alternative embodiments;

FIG. 10 is a cross-sectional view of system comprising a heat sink and a host component assembled with a hybrid bonded composite structure, in accordance with some embodiments;

FIG. 11 illustrates a mobile computing platform and a data server machine employing a multi-chip package, in accordance with some embodiments; and

FIG. 12 is a functional block diagram of an electronic computing device, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

As previously noted, hybrid bonding techniques offer advantages in the assembly of IC die structures to other IC die structures (active or passive) or some other host component, such as a package substrate structure, interposer structure, or the like. As used herein, an IC die structure may include any monolithic integrated circuit device that provides electrical, compute, memory, or similar functionality. An IC die structure may itself comprise more than one monolithic integrated circuit device. For example, an IC die structure may comprise two vertically stacked or coplanar IC dies. IC dies within an IC die structure may be directly bonded to each other or coupled through some intermediate routing structure. IC die structures in accordance with embodiments herein may be referred to as “chiplets,” “chiplet dies,” “dice,” “tiles,” or “chips,” for example. While the terms chiplet and IC die or chip may be used interchangeably, a fully functional ASIC is typically considered an IC die or chip while a chiplet or tile would have more limited functionality, for example supplementing one or more other IC chiplets that are to be part of the same multi-chiplet device. A chiplet or tile may, for example, be a wireless radio circuit, microprocessor core, electronic memory circuit, floating point gate array (FPGA), power management and/or power supply circuit, or include a MEMS device.

In the context of hybrid bonding IC die structures, self-alignment assisted assembly (SA3) may facilitate greater die-to-wafer hybrid bonding (D2 W HB) throughput by reducing the fine alignment burden. In some exemplary SA3 processes, bonding regions are incorporated into “biphilic” or “heterogeneous” structures on either (or both) an IC die structure or (and) a base substrate structure. As used herein, biphilic/heterogeneous structures comprise surfaces with a high wettability contrast between their distinct regions. As described further herein, a high wettability contrast can be achieved by physical patterning (e.g., creating trenches around the bonding area to confine liquid via the canthotaxis effect), chemical patterning (e.g., depositing hydrophobic coatings to lower surface energy around the bonding area), or combinations of the two (e.g., creating trenches with hydrophobically coated sidewalls surrounding the bonding area).

Within a biphilic structure, one region has high wettability relative to another region of low wettability. This wettability contrast can improve control of liquid droplet spreading such that a liquid droplet may be confined on a bonding region of either (or both) an IC die structure or (and) a base wafer. Surface tension of the droplet acts to passively fine-align the IC die structure as the droplet evaporates, leaving the bonding regions in contact and ready for hybrid bonding. At room temperature, attractive surface forces between the dielectric regions on the IC die structure and a base substrate structure may suffice to temporarily affix the two. A hybrid bond may be subsequently formed through application of pressure and/or elevated temperature to form and/or strengthen bonds between the metal features (e.g., copper pads) dispersed within surrounding dielectric material. Once bonded, the metal features form a composite metal feature that electrically interconnects an IC die structure and a base substrate structure. In some embodiments, however, bonding may be dielectric-dielectric only or metal-metal only (e.g., for thermal applications or some RF applications).

Accordingly, with SA3, a bonder may pick and place an IC die structure upon a base substrate structure in reliance on coarse alignment (e.g., ˜ 25-50 μm), enabling fast assembly. When a liquid droplet is confined to a bonding region between the IC die structure and the base substrate structure, capillary forces and liquid surface tension induce alignment with high positional accuracy (e.g., <200 nm) due to the biphilic structures present on mating surfaces of the IC die structure and/or base substrate structure. Such biphilic or heterogenous structures may therefore be more specifically referred to as “self-alignment features” or “SA3 features.”

The inventors have noted that while the relationship between droplet energy and IC die alignment is favorable for bonding surfaces having a high degree of co-planarity, the lowest energy state of a droplet surface may not correspond to an ideal alignment condition when bonding surfaces are not substantially parallel planes, and there is instead some non-zero magnitude of tilt of one bonding surface relative to the other. For example, when a die bonding head places an IC die structure upon a droplet, the head surface may have some degree of tilt relative a reference plane of the complementary bonding surface, which may be further defined by a workpiece chuck or pedestal of the bonder. The IC die structure, when released from the head to become supported by the droplet, may then be similarly non-parallel to the reference plane.

While the design of SA3 features may primarily seek to achieve lateral fine alignment by correcting in-plane displacements or rotations of an IC die structure resulting from inaccuracies in coarse alignment, if such features are incapable of correcting out-of-plane tilt, any incoming tilt of an IC die structure may be amplified when the die structure is released upon the liquid droplet (e.g. due to lack of coplanarity between the bond head and the pedestal). This may lead to assembly yield loss due to bonding or misalignment issues unless the challenges associated with tilt are adequately addressed by SA3 technology.

As described further below, embodiments herein comprise hybrid bonding of an IC die structure to a substrate structure as facilitated by liquid droplet-based fine alignment. To ensure superior alignment performance, the IC die structure and/or the substrate structure comprise a biphilic structure including one or more inner regions interspersed within the area of a die bonding site. The inner regions may be contiguous to bifurcate or divide a die bonding site into wholly separate bonding regions where different droplets may be contained. Alternatively, the inner regions may be segmented, for example to modulate how one or more droplets within contiguous bonding regions may respond to non-coplanarity between the bonding site and a complementary bonding site to which it is to bond. As further described below, a peripheral region outside of the bonding regions may also be segmented, for example to modulate how one or more droplets within the bonding regions may respond to non-coplanarity.

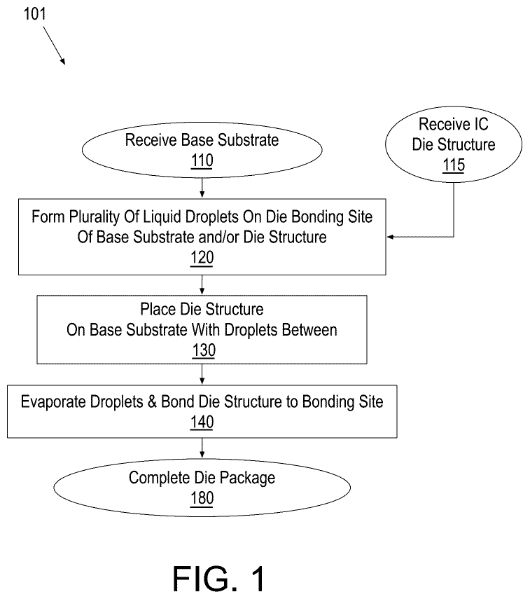

FIG. 1 is a flow diagram illustrating self-alignment assisted assembly (SA3) methods for integrated circuit (IC) die structures, in accordance with some embodiments. In methods 101, a plurality of liquid droplets are formed on a bonding site of either or both of an IC die structure or a base substrate structure that is to be bonded with the IC die structure. Methods 101 may be practiced, for example, to form one or more of the assemblies described elsewhere herein. Methods 101 are illustrated as including several discrete blocks to ensure clarity of description. However, in practice the number of blocks, and/or order of blocks, may be modified without departing from the principles illustrated by methods 101.

Methods 101 begin at input 110 where a base substrate structure is received. The base substrate structure may be any wafer, panel, or strip, etc. that is suitable for direct bonding with one or more IC die structures. A bonding site where an IC die structure is to be attached is integrated into one or more biphilic structures that are suitable for SA3 assembly.

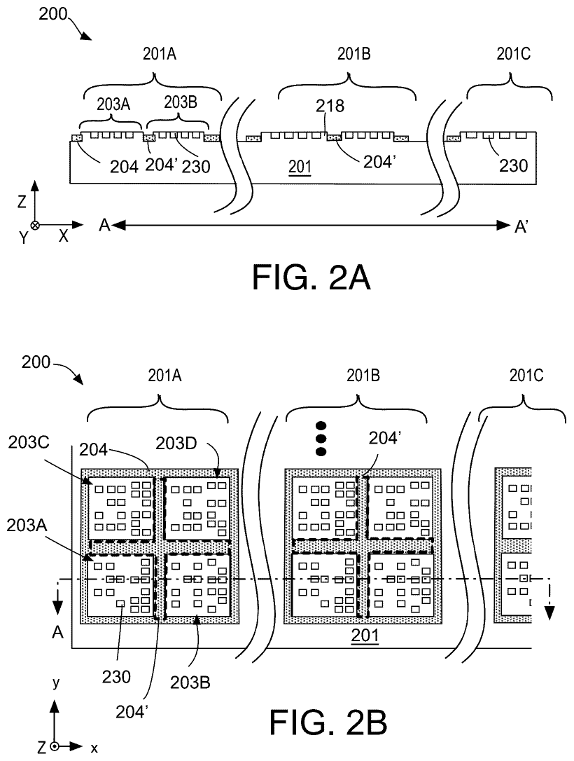

FIG. 2A is a cross-sectional view of a wafer (or panel) 200 comprising a plurality of aggregated “base” or “host” substrate structures 201A, 201B, 201C. In the illustrated example, each base substrate structure 201A-201C comprises one or more biphilic structures on a first (e.g., top) side of one or more substrate materials 201.

Substrate materials 201 may vary widely according to implementation. In some embodiments where each base substrate structure 201A-201C is a package substrate structure or package interposer, substrate materials 201 may include one or more structural material layers, such as silicon (e.g., monocrystalline), sapphire, or glass. Substrate materials 201 may include any of those found in an integrated circuit wafer having, such as semiconductor materials (e.g., silicon, germanium, GaN, GaAs, InP, InGaAS, etc), on-die interconnect layers (e.g., copper, aluminum, tantalum, other metals), and on-die dielectrics (e.g., silicon dioxide, carbon-doped silicon dioxide, silicon nitride, silicon carbide, etc.). For glass embodiments, the structural material may be predominantly silica (e.g., silicon and oxygen) and may further include one or more elements such as hydrogen, carbon and/or metals, such as, but not limited to copper, silver, gold, aluminum, beryllium, magnesium, calcium, strontium barium, or radium. Additional dopants (e.g., boron, phosphorus) may also be present in the structural material (e.g., borosilicate glass, etc.).

A package substrate structure or interposer may include one or more metallized redistribution or electrical routing levels (not depicted) embedded within a package dielectric material. The package dielectric material may have been built up on one or more sides of a structural material layer, for example. Structural material layers may be retained or ultimately discarded so that substrate materials 201 may comprise only package dielectric material and embedded routing metallization. Package dielectric material may be any organic dielectric, such as, an epoxy resin, phenolic-glass, or a resinous film such as the GX-series films commercially available from Ajinomoto Fine-Techno Co., Inc. (ABF). Package dielectric material may comprise epoxy resins (e.g., an acrylate of novolac such as epoxy phenol novolacs (EPN) or epoxy cresol novolacs (ECN)). In other examples, package dielectric material includes aliphatic epoxy resin, which may be monofunctional (e.g., dodecanol glycidyl ether), difunctional (butanediol diglycidyl ether), or have higher functionality (e.g., trimethylolpropane triglycidyl ether).

Substrate materials 201 may include one or more IC die structure (not depicted). In some embodiments, an IC die structure is embedded within package dielectric material. In other embodiments, each base substrate structure 201A-201C is an IC die structure. Such IC die structures may be fully functional ASICs, or may be chiplets or tiles of more limited functionality to supplement one or more other IC die structures that are to be part of the same multi-chip device. For embodiments where base substrate structure 201A-201C is an IC die structure, substrate materials 201 may include any of those materials typical of monolithically fabricated IC dies, such as, but not limited to, a device material layer and/or a silicon (e.g., monocrystalline) layer, and inorganic dielectric materials (e.g., comprising at least 20 atomic % of one or more of silicon, oxygen, or nitrogen).

Base substrate structures 201A-201C have biphilic surface structures with a wettability contrast between a peripheral region 204 of low wettability and adjacent bonding regions 203A and 203B, each of high wettability where a liquid droplet is to be formed. Although the liquid may vary (polar or non-polar, etc.), in exemplary SA3 embodiments employing water, the bonding regions 203A, 203B of high wettability are hydrophilic (i.e., inducing a water droplet to have a contact angle of less than) 90°. A water droplet will therefore tend to spread out over regions 203A, 203B as the liquid minimizes its surface energy. The adjacent peripheral region 204 of low wettability is hydrophobic (i.e., inducing a water droplet to have a large contact angle of greater than) 90°. A water droplet on regions 203A, 203B will tend to minimize contact with peripheral region 204.

For exemplary embodiments where regions 203A, 203B are a hydrophilic material, regions 203A, 203B may advantageously comprise one or more metal features 230 embedded in and/or dispersed over a dielectric material 218. Each of metal features 230 may comprise any metal known to be suitable for direct bonding. Metal features 230 may be predominantly Cu, for example. One or more of metal features 230 are advantageously electrically coupled to host component routing metallization and/or circuitry (not depicted). Metal features 230 are therefore to both electrically couple and physically affix base substrate structures 201A-201C to an IC die structure.

Dielectric material 218 may have any chemical composition suitable for hybrid bonding. Dielectric material 218 is advantageously an inorganic material, for example comprising at least 20 atomic % of one or more of silicon, oxygen, or nitrogen. In some embodiments, dielectric material 218 is primarily silicon and oxygen (e.g., SiO2), primarily silicon and nitrogen (e.g., Si₃N₂), or primarily silicon, oxygen and nitrogen (e.g., SixOyNx), any of which may further comprise one or more dopants, such as carbon. Inorganic dielectric materials are nevertheless distinct from organic dielectrics (e.g., epoxy resins and phenolic-glasses), which have much higher carbon content and a higher percentage of carbon-hydrogen bonds.

For some exemplary embodiments where peripheral region 204 is a hydrophobic material, peripheral region 204 may include any chemical coating or thin film material and/or topographic structure that creates a hydrophobic boundary adjacent to one or more edges of bonding regions 203A, 203B. In some embodiments, the hydrophobic material is a self-assembled monolayer (SAM) material such as an alkyl or fluoroalkyl silane (e.g., ODS, FDTS), a thiol (e.g., hexadecane thiol), a phosphonic acid (e.g., octadecyl or perfluorooctane phosphonic acid), or an alkanoic acid (e.g., heptadecanoic acid). Other SAM embodiments may comprise disulfides, amines, azoles, amides, imides, pyridine derivatives, cyanoacrylate derivatives or other moieties which include a sulfur atom or a nitrogen atom. SAM reactions typically form monolayer molecules aligned with each other in a uniform manner. Such a molecule may be introduced in the vapor phase and “self-assemble” by forming a highly selective bond at the surface and orientating itself perpendicular to the face of the surface. However, non-SAM based materials or films are also possible. In some embodiments, peripheral region 204 is, or includes, a polymer thin film such as a siloxane (e.g., PDMS and derivatives, HMDSO), a silazane (HMDS), a polyolefin (e.g., PP), or a fluorinated polymer (e.g., PTFE, PFPE, PFDA, C₄F₈ plasma polymerized films, etc.). In some advantageous embodiments, region 204 comprises a material of a chemical composition having at least ten atomic percent (at. %) carbon or at least ten at. % fluorine.

Peripheral region 204 may additionally, or in the alternative, comprise topographic features that increase wettability contrast relative to bonding regions 203A, 203B. A topographic trench within peripheral region 204 may, for example, improve wettability contrast between regions 204 and bonding regions 203A, 203B. Such a topographic feature can change a liquid droplet's effective contact angle to greater than 90° and thereby alter the surface energy characteristics of the droplet. In some further embodiments, peripheral region 204 has significantly higher average surface roughness than bonding regions 203A, 203B. Region 204 may be roughened with any surface texturing techniques, such as laser surface roughening. Roughened surfaces may have any surface roughness greater than the surface roughness of bonding regions 203A, 203B. For example, bonding regions 203A, 203B may have a low surface roughness (e.g., <30 nm average roughness) while peripheral region 204 has high surface roughness (e.g., >50 nm average roughness). In some embodiments, the average surface roughness of peripheral region 204 is at least twice the average surface roughness of the surface of bonding regions 203A, 203B and may be five, ten, or twenty times that of bonding regions 203A, 203B. As used herein, average roughness (or center line average) is as described in ASME B46.1. Average roughness is the arithmetic average of the absolute values of profile height deviations from a mean line that is recorded for an evaluation length. Average roughness may be measured, for example, with a profilometer comprising a stylus that is traversed over a surface. For region 204 having a longitudinal length in a first dimension (e.g., coincident with x-axis), average roughness may be measured over a distance roughly 60-70% of the longitudinal length while remaining at about a centerline of a transverse width of region 204 that is in a dimension substantially orthogonal to the first dimension (e.g., coincident with y-axis).

As further illustrated in FIG. 2A, an inner region 204′ is between two adjacent bonding regions 203A and 203B. Inner region 204′ also has wettability contrast with bonding regions 203A and 203B. Inner region 204′ may have any of the compositions, topographic features, and/or surface characteristics described for peripheral region 204. In some exemplary embodiments, inner region 204′ has substantially the same chemical composition, surface topography, and/or surface characteristics as peripheral region 204. Alternatively, inner region 204′ may have a different chemical composition, surface topography, and/or surface characteristics than peripheral region 204.

FIG. 2B is a plan view of base wafer or panel 200, in accordance with some embodiments. The A-A′ cross-sectional plane illustrated in FIG. 2A is denoted in FIG. 2B by a dashed line. As further illustrated in FIG. 2B, bonding regions 203A, 203B are two of four bonding regions that further include regions 203C and 203D. Each base substrate structure 201A-201C therefore has four bonding regions 203A-203D, and peripheral region 204 is adjacent to an outer edge of regions 203A-203D. Bonding regions 203A-203D are further delineated by inner region 204′, demarked in heavy dashed line. In this example, inner region 204′ is substantially contiguous with peripheral region 204. Peripheral region 204 is a contiguous perimeter frame while inner region 204′ is a contiguous intervening dodecagon separating quadrants of a 2D grid. One of regions 203A-203D is within each quadrant. As described further below, such a 2D array of bonding regions may be advantageous for mitigating tilt or non-planarity between bonding sites, which may be in one or more of an x-dimension or y-dimension.

Relative to inner region 204′ and peripheral region 204, bonding regions 203A-D may be of contrasting feature shapes, and/or of contrasting surface roughness, and/or of contrasting chemical composition. In the example illustrated by FIG. 2A-2B, both peripheral region 204 and inner region 204′ are in contact with a sidewall of bonding regions 203A-D. As described further below, bonding regions 203A-D match a desired layout of a single IC die structure that is to be attached to each base substrate structure 201A-201C. Peripheral regions 204 and inner regions 204′ are in this example within a trench formed within one or more substrate materials 201. Alternatively, bonding regions 203A-B may each be a pedestal or mesa over substrate materials 201.

Peripheral regions 204 and inner regions 204′ are each adjacent to multiple non-parallel edges of each bonding region (e.g., 203A, 203B). Regions 204, 204′ may be formed on sidewalls of bonding regions 203A-D according to any suitable technique(s). For example, a conformal hydrophobic material layer may be formed on exposed surfaces of bonding regions 203A-D, for example with either a spin coating or a conformal vapor deposition process. The conformal hydrophobic material layer may then be patterned with an anisotropic “spacer” etch.

Returning to FIG. 1, methods 101 receive an IC die structure at a second input 115. The IC die structure received at input 115 may comprise a single IC die or may comprise any number of IC dies assembled (e.g., hybrid bonded) into a coplanar or 3D IC die structure. The IC die structure may, but need not, further comprise organic dielectric materials and/or metallization levels built up upon an IC die surface with a suitable semi-additive process (SAP).

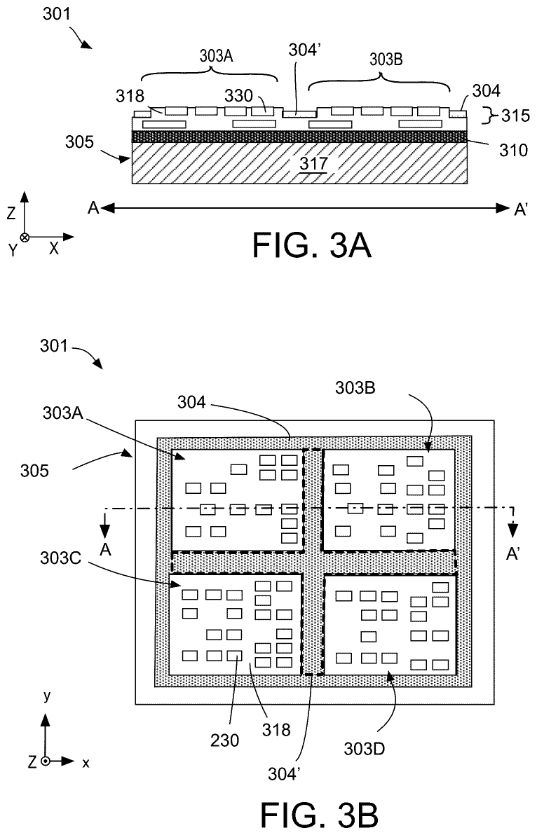

FIG. 3A is a cross-sectional view of an IC die structure 301 comprising one or more biphilic structures within a bonding site, in accordance with some embodiments. FIG. 3B is a plan view of the IC die structure illustrated in FIG. 3A, in accordance with some embodiments. In FIG. 3B, the cross-sectional line illustrated in FIG. 3A is denoted with a dashed A-A′ line.

In the exemplary embodiments illustrated by FIG. 3A and FIG. 3B, IC die structure 301 comprises an IC die substrate material 317, a device layer 310 in contact with IC die substrate material 317, and IC die metallization levels 315 over device layer 310. Although not illustrated, IC die structure 301 may include through substrate structure vias (TSVs) extending from device layer 310 and into IC die substrate material 317. Chemical composition of IC die substrate material 317 may vary with implementation. In exemplary embodiments, IC die substrate material 317 is a silicon (e.g., monocrystalline) layer. IC die substrate material 317 may also be of alternative compositions, such as, but not limited to, germanium (Ge), silicon germanium alloys (SiGe), gallium arsenide alloys (GaAs), indium phosphide alloys (InP), gallium nitride alloys (GaN), silicon carbide alloys (SiC), etc. Device layer 310 comprises active devices (not depicted). In some embodiments, the active devices within device layer 310 are field effect transistors (FETs). The FETs may be of any architecture (e.g., planar, non-planar, single-gate, multi-gate, stacked nanosheet, etc.) and may have a feature pitch of 5-30 nm. Additionally, or in the alternative, device layer 310 may include active devices other than FETs. For example, device layer 310 may include electronic memory structures, spin valves, or the like.

IC die structure 301 comprises IC die metallization levels 315 on a front side of device layer 310. In exemplary embodiments, metallization levels 315 include die metallization features 330 embedded within dielectric material 318. While IC die metallization features 330 may have any composition(s) of sufficient electrical conductivity, in exemplary embodiments, IC die metallization features 330 are predominantly Cu. In other examples, metallization features 330 are predominantly other than Cu, such as, but not limited to predominantly Ru, or predominantly W.

IC die structure 301 further comprises a biphilic structure corresponding to a complementary structure on a base substrate structure 201A (FIG. 2A-B). For IC die structure 301 (FIG. 3A), bonding regions 303A and 303B comprise an uppermost one of metallization features 330. Bonding regions 303A and 303B may have any feature pitch compatible with bonding regions 203A, 203B (FIG. 2A), respectively. In some exemplary embodiments, individual ones of metallization features 330 (FIG. 3A) correspond to individual ones of metallization features 230 (FIG. 2A), both having a feature pitch in the range of 20 nm to 1 μm, for example. Metallization features 330 (FIG. 3A) may have any suitable composition and may be of substantially the same composition as metallization features 230 (FIG. 2A), as one example. Bonding regions 303A, 303B (FIG. 3A) further comprise a dielectric material 318, which may have any of the inorganic compositions described for dielectric material 218. Bonding regions 330A, 330B are therefore highly compatible for hybrid bonding with bonding regions of a corresponding base substrate structure.

IC die structure 301 further comprises a peripheral region 304 adjacent to one or more outer edges of bonding regions 203A, 203B. Peripheral region 304 is within a footprint of IC die structure 301 defined by a die edge sidewalls 305. Peripheral region 304 may have any of the properties or characteristics discussed elsewhere herein for peripheral region 204 (FIG. 2A). In some embodiments, bonding regions 203A, 203B and peripheral region 304 are each fabricated according to any of the techniques discussed above for corresponding biphilic regions of a base substrate structure. The biphilic surface structures on a base substrate structure and the biphilic structures on an IC die structure may be substantially the same (as illustrated) or they may differ compositionally and/or structurally.

As illustrated in FIG. 3A, an inner region 304′ is between two adjacent bonding regions 203A and 203B. Inner region 304′ also has wettability contrast with bonding regions 303A and 303B. Inner region 304′ may have any of the compositions, topographic features, and/or surface characteristics described for inner region 204′ (FIG. 2B), peripheral region 204, or peripheral region 304 (FIG. 3A, 3B). In some exemplary embodiments, inner region 304′ has substantially the same chemical composition, surface topography, and/or surface characteristics as peripheral region 304. Alternatively, inner region 304′ may have a different chemical composition, surface topography, and/or surface characteristics than peripheral region 304.

As illustrated in FIG. 3B, bonding regions 303A, 303B are two of four bonding regions further including regions 303C and 303D. IC die structure 301 therefore has four bonding regions 303A-303D, and peripheral region 304 is adjacent to an outer edge of regions 303A-303D. Bonding regions 303A-303D are further delineated by inner region 304′, demarked in heavy dashed line. In this example, inner region 304′ is substantially contiguous with peripheral region 304. Peripheral region 304 is a contiguous perimeter frame while inner region 304′ is a contiguous intervening dodecagon separating quadrants of a 2D grid. One of regions 303A-303D is within each quadrant. Relative to inner region 304′ and peripheral region 304, bonding regions 303A-D may be of contrasting feature shapes, and/or of contrasting surface roughness, and/or of contrasting chemical composition. In the example illustrated by FIG. 3A-3B, both peripheral region 304 and inner region 304′ are in contact with a sidewall of bonding regions 303A-D. As described further below, bonding regions 303A-D match complementary structures of a base substrate structure to which IC die structure 301 is to be bonded. In this example, both peripheral region 304 and inner region 304′ are in a trench formed within dielectric material 318. Alternatively, bonding regions 303A-B may each be a pedestal or mesa over IC die metallization levels 315.

Regions 304, 304′ are each adjacent to multiple non-parallel edges of each bonding region (e.g., 303A, 303B). Peripheral region 304 and inner region 304′ may be formed on sidewalls of bonding regions 303A-D according to any suitable technique(s). For example, a conformal hydrophobic material layer may be formed on exposed surfaces of bonding side regions 303A-D, for example with either a spin coating or a conformal vapor deposition process. The conformal hydrophobic material layer may then be patterned with an anisotropic “spacer” etch.

Peripheral region 304 and inner region 304′ may be a single continuous material and/or structure with a hydrophobic surface. Alternatively, regions 304, 304′ may comprise multiple discontinuous hydrophobic material and/or structural segments delineating a perimeter about two or more edges of bonding region 303. FIG. 3A and FIG. 3B illustrate an example where IC die structure 301 comprises a 2D x-y grid of bonding regions. As described further below, such a 2D array may be advantageous for mitigating tilt or non-planarity between bonding surfaces, which may be in one or more of an x-dimension or y-dimension.

Returning to FIG. 1, methods 101 continue at block 120 where a liquid droplet is formed on each of a plurality of bonding regions of a base substrate structure and/or a corresponding IC die structure. Any techniques suitable for a particular liquid, such as vapor condensation or direct liquid dispense (i.e., printing) may be practiced at block 120 as embodiments are not limited in this respect. In some exemplary embodiments, an aqueous (e.g., water) droplet is dispensed at block 120. However, alternative polar liquids (e.g., alcohols) or non-polar liquids (e.g., solvents) may be dispensed at block 120 depending on the nature of the wettability contrast of a biphilic structure on a base substrate structure and/or IC die structure.

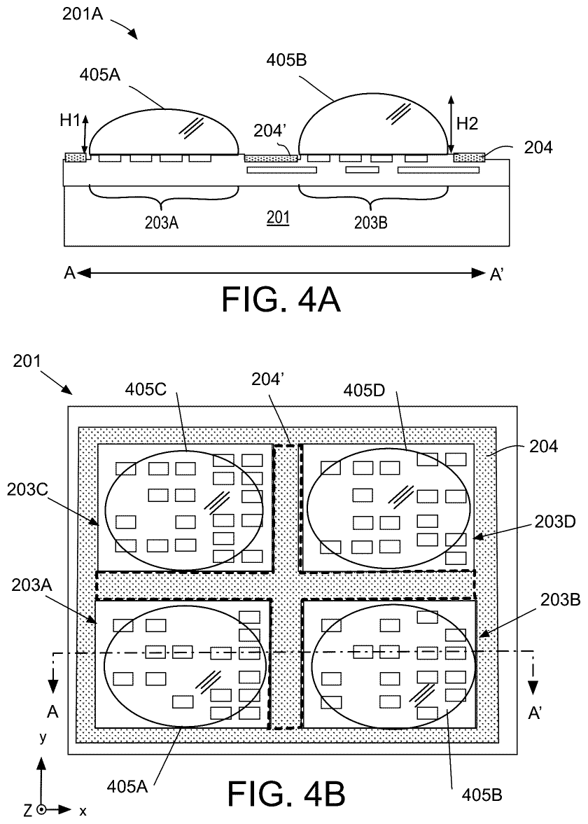

FIG. 4A is a cross-sectional view of base substrate structure 201A with a plurality of liquid droplets 405A, 405B on IC die bonding regions 203A, 203B, respectively. FIG. 4B is a plan view of base substrate structure 201A further illustrating droplets 405A and 405B to be two of four liquid droplets 405A-405D. Each droplet 405A-405D is confined to a corresponding bonding region 203A-203D. Confinement of liquid droplets 405A-405D by peripheral region 204 and inner region 204′ is similar to confinement of liquid droplets formed over one or more base substrate structures that are to couple with multiple IC die structures. According to embodiments herein, however, base substrate structure 201A is to receive a single IC die structure with the multiple liquid droplets 405A-405D to mitigate non-planarity between base substrate structure 201A and the IC die structure with which it is to be bonded.

The presence of multiple droplets to a single die bonding site adds a degree of freedom to independently vary the droplet volume and/or otherwise modulate properties of each droplet across the plurality of droplets. For example, in some embodiments, liquid droplets 405A-405D comprise a significantly different liquid volume. As shown in FIGS. 4A and 4B, for example, liquid droplet 405B has a larger volume than liquid droplet 405A. For embodiments where bonding region 203B has substantially the same area as bonding region 203A (as illustrated in FIG. 4B), the greater liquid volume results in droplet 405B having a vertical (e.g., z-dimension) height H2 that is greater than height H1 of droplet 405A. Such variation in droplet volume and/or height may mitigate non-planarity between an x-y plane of base substrate structure 201A and that of an IC die to be bonded.

In other embodiments, even where droplet volume is substantially the same across all droplets 405A-405D, inner region 204′ and/or peripheral region 204 may have a significant variation either due to their polygonal shape(s) or surface characteristics to independently vary wetting area of each droplet across the plurality of droplets. For example, although the bonding regions 203A-203D are illustrated as all being substantially of the same x-y dimensions, one or more bonding regions may instead be of smaller (larger) area than the remainder. For example, where bonding region 203B is of a smaller area than bonding region 203A, droplet 405B may again have a vertical (e.g., z-dimension) height H2 greater than height H1 of droplet 405A even if both droplets have substantially the same liquid volume.

With droplets formed, methods 101 (FIG. 1) continue at block 130 where the IC die structure received at input 115 is placed over a bonding site of the base substrate structure received at input 110. Block 130 may be implemented with a pick and place machine associated with some finite positional accuracy and precision, for example.

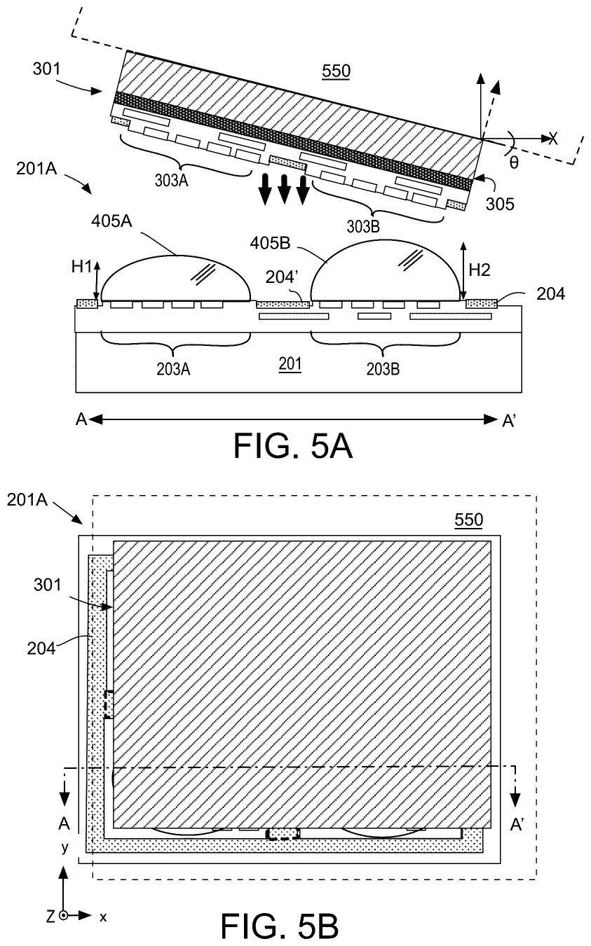

FIG. 5A is a cross-sectional view of IC die structure 301 being coarse aligned and placed upon a plurality of liquid droplets that include droplets 405A, 405B, in accordance with some embodiments. FIG. 5B is a plan view of alignment and placement of IC die structure 301. FIG. 5A illustrates a non-zero tilt, elevation, or inclination angle θ associated with IC die head 550. Depending on machine set up, angle of head inclination θ may be up to a few degrees off-level (e.g., 0.1°-2°) relative to a reference x-y plane of a pedestal or chuck that is level and supporting substrate structure 201A.

Head inclination angle θ may be mapped to corresponding x-y components. A non-zero tilt θ may be mitigated, for example, through an assembly qualification process whereby test IC die structures may be repeatedly positioned upon liquid droplets 405A-405D of a size varied as a control variable with a resulting x-y fine alignment for each treatment measured as a response variable so as to arrive at a menu of liquid droplet properties that minimizes misalignment. In the example illustrated in FIG. 5A, a head inclination angle θ has an x-component causing bonding region 303A to trail bonding region 303B during an approach to base substrate structure 201A. Liquid droplet 405B, being of greater height H2, may ensure the leading die edge sidewall 305 is suspended upon droplet 405B despite an approach angle that may otherwise induce early contact between the leading die edge sidewall 305 and a bonding surface of base substrate structure 201A. Although only the x-component is illustrated in FIG. 5A, a head inclination angle may also have a non-zero y-dimensional component that may be similarly mitigated by varying droplet height, for example between liquid droplets 405A and 405C (FIG. 4B) and/or droplets 405B and 405D. Hence, while as few as two die bonding regions may be provisioned for a given die bonding site, providing at least three die bonding regions can advantageously define a plane for accommodating or mitigating tilt in both x and y dimensions.

Some lateral (x-y) alignment error is illustrated in FIG. 5B with liquid (e.g., water) droplets 405A-405D to correct the misalignment during a passive fine alignment (e.g., via capillary forces, etc.) phase until the droplet evaporates. In exemplary embodiments, the fine alignment is advantageously to within 200 nm in each of the x-dimension and orthogonal y-dimension. Such fine alignment may be achieved from a coarse alignment that is to within 25 μm in each of the x-dimension and orthogonal y-dimension, assuming any non-zero tilt angle θ is mitigated to the point that the fine alignment process can proceed substantially unimpeded.

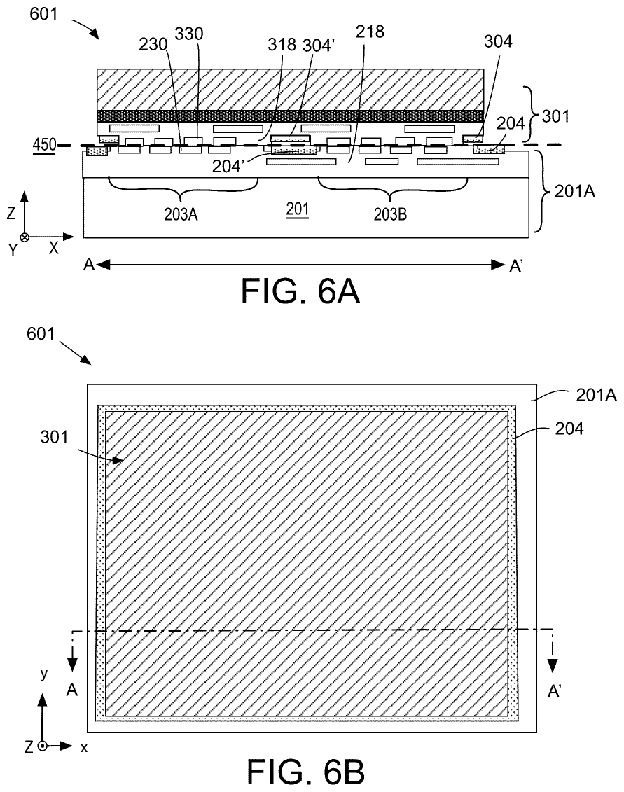

Returning to FIG. 1, methods 101 continue at block 140, where a liquid droplet between an IC die structure and base substrate structure is evaporated, bringing the IC die structure bonding regions in direct contact with the base substrate structure bonding regions. The IC die structure is then bonded to the base substrate structure according to any suitable hybrid bonding technique(s). FIG. 6A illustrates an exemplary hybrid bonded composite structure 601 where IC die structure 301 is now in contact with base substrate structure 201A along bonding interface 450, denoted by a thick dashed line. As shown, metal features 230 are in direct contact with at least a portion of corresponding ones of metal features 330. Dielectric material 218 of base substrate structure 201A is likewise in direct contact with dielectric material 318 of IC die structure 301. An extent of lateral offset between metal features 230 and 330 along bonding interface 450 in each of the x-dimension and y-dimension is indicative of the tolerances achieved by the self-alignment fine alignment process.

In the illustrated example, peripheral region 204 of the biphilic structures on base substrate structure 201A is co-located with a corresponding peripheral region 304 on IC die structure 301. Peripheral region 204 may also be in direct contact with peripheral region 304 along bonding interface 450, although the two may not interdiffuse or meld to form a unified composite structure even after a thermal and/or compression bonding process. Peripheral region 204 may also be physically spaced apart from peripheral region 304 across bonding interface 450. Inner region 204′ is likewise co-located with a corresponding inner region 304′. Inner regions 204′, 304′ may also be in direct contact, although they may not interdiffuse or meld to form a unified composite structure even after a thermal and/or compression bonding process. Inner regions 204′, 304′ may also be physically spaced apart across bonding interface 450, depending on topography of the biphilic surface structures.

Returning to FIG. 1, methods 101 end at output 180 where an IC die package is completed according to any known techniques. For example, an encapsulation or fill material may be deposited over a bonded IC die structure, and over portions of the base substrate structure that is not occluded by the IC die structure. The fill material is advantageously a dielectric material and may be an inorganic or organic dielectric material, such as any of those previously described. In some embodiments the fill material is deposited to a thickness at least equal to the thickness of the IC die structure. The fill material may be deposited by any technique known to be suitable for the chosen composition and thickness of material. Depending on the deposition process, the dielectric fill material may be planar along a length spanning both the IC die structure and beyond an edge of the IC die structure. The encapsulation and/or fill material may also be planarized, for example with a chemical mechanical planarization (CMP) system or other suitable grinder and/or polisher. The planarization process may also thin the bonded IC die structure by a significant amount. Planarization processes may thin the bonded IC die structure to the limit of workpiece total thickness variation (TTV). In some embodiments, the thickness of an IC die substrate structure (e.g., silicon layer) is reduced by at least 30%, and advantageously at least 80%. Any known processing may then be performed to arrive at a singulated hybrid-bonded IC die package/assembly.

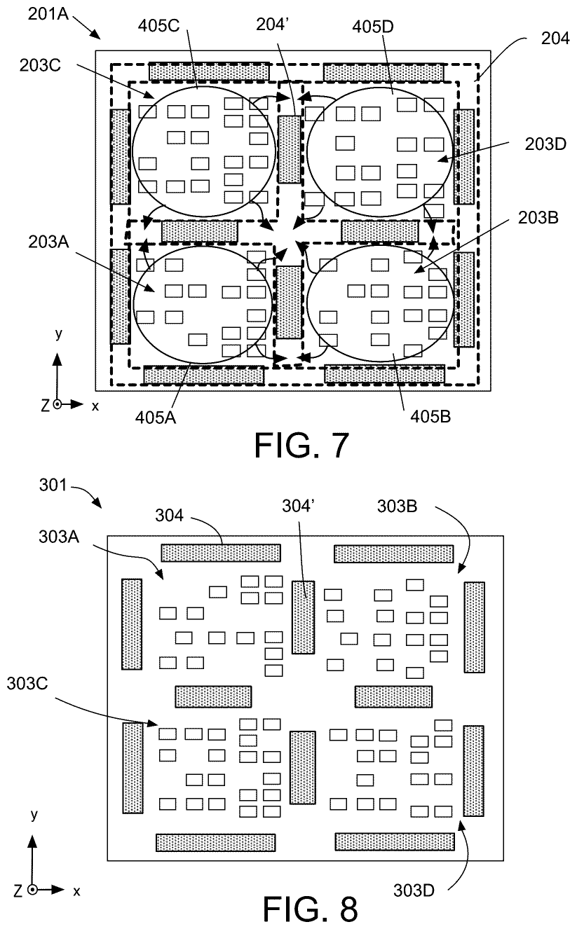

In some embodiments, one or more of a peripheral or inner region of a biphilic structure comprises segments separated by one or more bonding regions. For embodiments where an inner region comprises segments surrounded by contiguous bonding regions, the segment design may modulate how a liquid droplet in one bonding region may transport to another bonding region, for example in response to an approaching IC die structure that is not ideally co-planar with the bonding regions. FIG. 7 is a plan view of liquid droplets 405A, 405B, 405C and 405D on bonding regions 203A, 203B, 203C and 203D, respectively. As illustrated, inner regions 204′ comprise four segments surrounded by contiguous bonding regions 203A-203D. Liquid transport paths around the inner regions 204′ are denoted by arrows. Liquid droplets 405A-405D may therefore begin as four discrete droplets and subsequently merge into fewer droplets, for example in response to contact with corresponding bonding regions (e.g., on an IC die structure). Such intra-site liquid transport may mitigate a lack of co-planarity between two opposing bonding site surfaces that are to be bonded and/or otherwise improve fine alignment of an IC die structure to a base substrate structure.

As further illustrated in FIG. 7, peripheral region 204 is similarly segmented with two orthogonally oriented peripheral region segments demarking a perimeter of each bonding region 203A-203D. Segmentation of peripheral region 204 may provide liquid transport paths through which a volume of liquid may escape the bonding regions 203A-203D, for example, in response to contact with corresponding bonding regions (e.g., on an IC die structure). Such inter-site liquid transport may also mitigate a lack of co-planarity between two opposing bonding site surfaces that are to be bonded and/or otherwise improve fine alignment. Although both segmented inner and peripheral regions are illustrated in FIG. 7, either one may be implemented without the other.

FIG. 8 is a plan view of a bonding site of IC die structure 301, in accordance with some alternative embodiments. As shown, bonding regions 303A-303D have a complementary metallization pattern to that of bonding regions 203A-203D shown in FIG. 7. Bonding regions 303A-303D are similarly surrounded by a segmented peripheral region 304. Bonding regions 303A-303D also similarly surround a segmented inner region 304′. Such segmentation may also provide intra-bonding site and inter-bonding site liquid transport paths through which a volume of liquid may move to/from one or more of the bonding regions 303A-303D, for example in response to non-planarity between bonding sites.

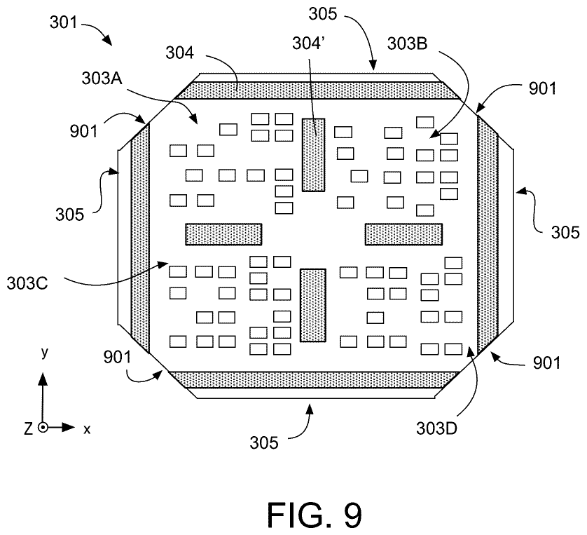

In some embodiments, an IC die structure has a polygonal shape other than rectangular. The non-rectangular shape, may for example, help to modulate liquid transport to/from one or more bonding sites during a liquid droplet-based fine alignment process. FIG. 9 is a plan view of a bonding site of IC die structure 301, in accordance with some alternative embodiments. As shown, IC die structure 301 has four orthogonal edge sidewalls 305. Two edge sidewalls 305 are each intersected by a third edge sidewall 901. In the illustrated example, third edge sidewall 901 chamfers each corner of IC die structure 301 resulting in an octagonal shape. Such a polygon may react to non-planarity between bonding sites differently from a rectangular IC die structure. In the illustrated example, each edge sidewall 901 also intersects one bonding region 303A-303D such that there is a break in peripheral region 304 at each chamfered corner. Peripheral region 304 is therefore again segmented albeit by the IC die edge sidewalls 901 rather than through a patterning of the biphilic surface structures. Peripheral region 304 therefore extends the entire length of IC die edge sidewalls 305. Inner region 304′ is again illustrated as discrete segments surrounded by die bonding regions 303A-303D. Alternatively, inner region 304′ may be contiguous with peripheral region 304, or absent altogether as the various embodiments described herein may be combined together or implemented individually, for example as one or more means of modulating a liquid droplet-based fine alignment process.

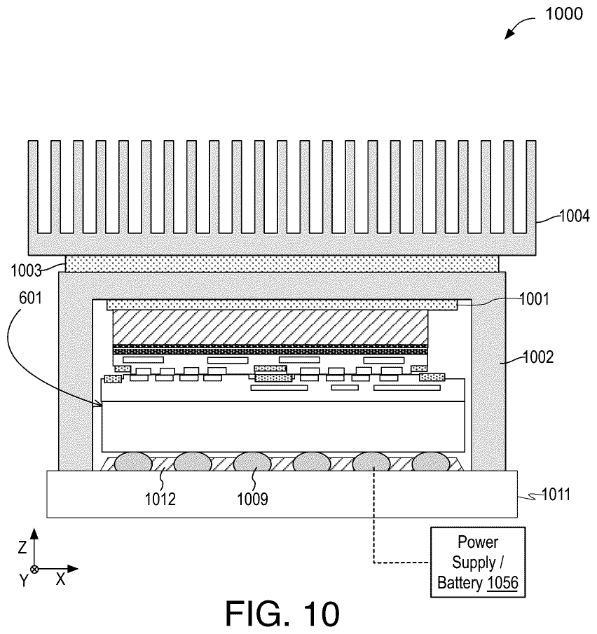

FIG. 10 is a cross-sectional view of system 1000 comprising a heat sink 1004 and a host component 1011 assembled with a hybrid bonded composite structure 601 further comprising a hybrid bonded IC die, in accordance with some embodiments. Although illustrated with an integration of composite structure 601, system 1000 may similarly comprise a composite structure including one or more of the alternative IC die structures and/or base substrate structures described herein. System 1000 may include any number of such composite structures mounted to host component 1011 via interconnects 1009, which are optionally embedded in an underfill material 1012. Host component 1011 may be a cored or coreless package substrate structure, interposer, or board (such as a motherboard), for example.

System 1000 further includes a power supply 1056 coupled to one or more of host component 1011 (i.e., a board, package substrate structure, or interposer), composite structure 601, and/or other components of system 1000. Power supply 1056 may include a battery, voltage converter, power supply circuitry, or the like. System 1000 further includes a thermal interface material (TIM) 1001 over composite structure 601. TIM 1001 may include any suitable thermal interface material. System 1000 further includes an integrated heat spreader (IHS) and/or lid 1002 in contact with TIM 1001 and extends over composite structure 601. System 1000 further includes another TIM 1003 in contact with a top surface of IHS 1002. TIM 1003 may include any suitable thermal interface material and may be of the same composition as TIM 1001, or not. System 1000 includes a heat sink 1004 (e.g., an exemplary heat dissipation device or thermal solution) in contact with TIM 1003. System 1000 may be further integrated into a computer, such as a mobile device or server, for example.

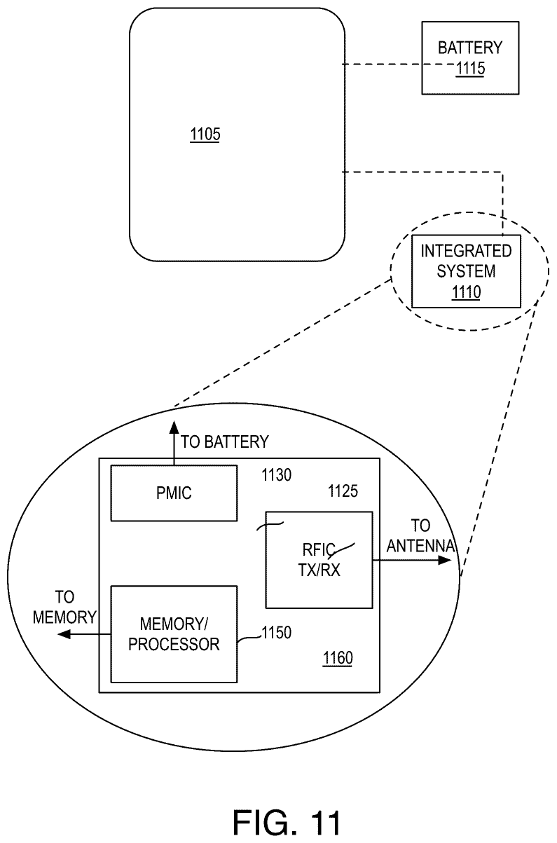

FIG. 11 illustrates an exemplary computer platform 1105 including a composite structure including a bonded IC die with biphilic features proximal to a hybrid bond interface indicative of droplet-based fine alignment techniques. Platform 1105 may be a mobile computing platform and/or a data server machine, for example. A server machine may be any commercial server, for example, including any number of high-performance computing platforms disposed within a rack and networked together for electronic data processing. Platform 1105 may be any portable device configured for each of electronic data display, electronic data processing, wireless electronic data transmission, or the like. Platform 1105 may include a chip-level or package-level integrated system 1110, and a battery 1115. In some examples, the disclosed systems may be implemented in a disaggregated sub-system 1160.

Sub-system 1160 may include memory circuitry and/or processor circuitry 1150 (e.g., RAM, a microprocessor, a multi-core microprocessor, graphics processor, etc.), a power management integrated circuit (PMIC) 1130, and a radio frequency integrated circuit (RFIC) 1125 (e.g., including a wideband RF transmitter and/or receiver (TX/RX)). As shown, one or more IC dice, such as memory circuitry and/or processor circuitry 1150 may be co-packaged and/or co-assembled within a composite structure including an IC die having biphilic structures proximately to a hybrid bond interface, for example as described herein.

In some embodiments, RFIC 1125 includes a digital baseband and an analog front end module further comprising a power amplifier on a transmit path and a low noise amplifier on a receive path). Functionally, PMIC 1130 may perform battery power regulation, DC-to-DC conversion, etc., and so has an input coupled to battery 1115, and an output providing a current supply to other functional modules. As further illustrated in FIG. 11, in the exemplary embodiment, RFIC 1125 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1150 may provide memory functionality, high level control, data processing and the like for sub-system 1160.

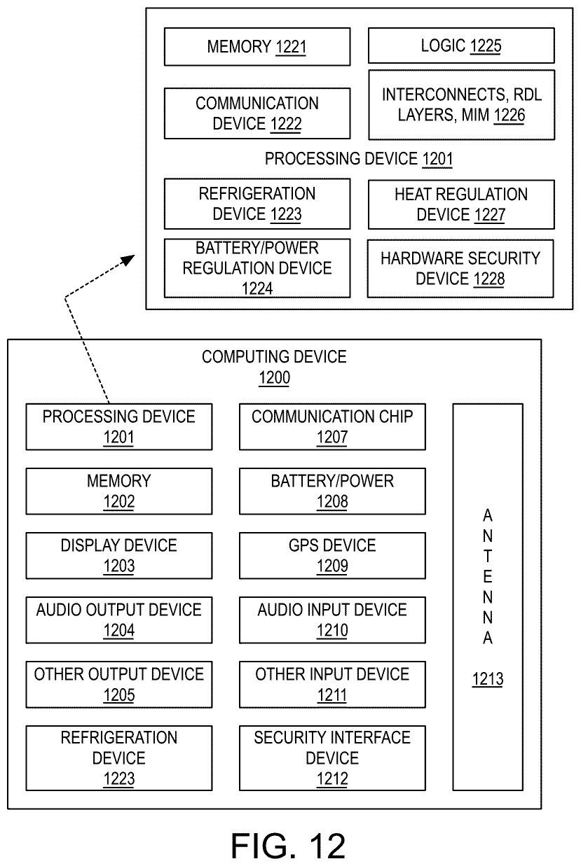

FIG. 12 is a block diagram of a cryogenically cooled computing device 1200 in accordance with some embodiments. For example, one or more components of computing device 1200 may include any of the devices or structures discussed elsewhere herein. A number of components are illustrated in FIG. 12 as included in computing device 1200, but any one or more of these components may be omitted or duplicated, as suitable for the application. In some embodiments, some of the components included in computing device 1200 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Additionally, in various embodiments, computing device 1200 may not include one or more of the components illustrated in FIG. 12, but computing device 1200 may include interface circuitry for coupling to the one or more components. For example, computing device 1200 may not include a display device 1203, but may include display device interface circuitry (e.g., a connector and driver circuitry) to which display device 1203 may be coupled.

Computing device 1200 may include a processing device 1201 (e.g., one or more processing devices). As used herein, the term processing device or processor indicates a device that processes electronic data from registers and/or memory to transform that electronic data into other electronic data that may be stored in registers and/or memory. Processing device 1201 may include a memory 1221, a communication device 1222, a refrigeration/active cooling device 1223, a battery/power regulation device 1224, logic 1225, interconnects 1226, a heat regulation device 1227, and a hardware security device 1228.

Processing device 1201 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1201 may include a memory 1202, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing 1201 shares a package with memory 1202. This memory may be used as cache memory and may include embedded dynamic random-access memory (eDRAM) or spin transfer torque magnetic random-access memory (STT-M RAM).

Computing device 1200 may include a heat regulation/refrigeration device 1223. Heat regulation/refrigeration device 1223 may maintain processing device 1201 (and/or other components of computing device 1200) at a predetermined low temperature during operation. This predetermined low temperature may be any temperature discussed elsewhere herein.

In some embodiments, computing device 1200 may include a communication chip 1207 (e.g., one or more communication chips). For example, the communication chip 1207 may be configured for managing wireless communications for the transfer of data to and from computing device 1200. The term “wireless” and its derivatives may be used to describe circuits, devices, systems, methods, techniques, communications channels, etc., that may communicate data through the use of modulated electromagnetic radiation through a nonsolid medium.

Communication chip 1207 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1207 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1207 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1207 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1207 may operate in accordance with other wireless protocols in other embodiments. Computing device 1200 may include an antenna 1213 to facilitate wireless communications and/or to receive other wireless communications (such as AM or FM radio transmissions).

In some embodiments, communication chip 1207 may manage wired communications, such as electrical, optical, or any other suitable communication protocols (e.g., the Ethernet). As noted above, communication chip 1207 may include multiple communication chips. For instance, a first communication chip 1207 may be dedicated to shorter-range wireless communications such as Wi-Fi or Bluetooth, and a second communication chip 1207 may be dedicated to longer-range wireless communications such as GPS, EDGE, GPRS, CDMA, WiMAX, LTE, EV-DO, or others. In some embodiments, a first communication chip 1207 may be dedicated to wireless communications, and a second communication chip 1207 may be dedicated to wired communications.

Computing device 1200 may include battery/power circuitry 1208. Battery/power circuitry 1208 may include one or more energy storage devices (e.g., batteries or capacitors) and/or circuitry for coupling components of computing device 1200 to an energy source separate from computing device 1200 (e.g., AC line power).

Computing device 1200 may include a display device 1203 (or corresponding interface circuitry, as discussed above). Display device 1203 may include any visual indicators, such as a heads-up display, a computer monitor, a projector, a touchscreen display, a liquid crystal display (LCD), a light-emitting diode display, or a flat panel display, for example.

Computing device 1200 may include an audio output device 1204 (or corresponding interface circuitry, as discussed above). Audio output device 1204 may include any device that generates an audible indicator, such as speakers, headsets, or earbuds, for example.

Computing device 1200 may include an audio input device 1210 (or corresponding interface circuitry, as discussed above). Audio input device 1210 may include any device that generates a signal representative of a sound, such as microphones, microphone arrays, or digital instruments (e.g., instruments having a musical instrument digital interface (MIDI) output).

Computing device 1200 may include a global positioning system (GPS) device 1209 (or corresponding interface circuitry, as discussed above). GPS device 1209 may be in communication with a satellite-based system and may receive a location of computing device 1200, as known in the art.

Computing device 1200 may include another output device 1205 (or corresponding interface circuitry, as discussed above). Examples include an audio codec, a video codec, a printer, a wired or wireless transmitter for providing information to other devices, or an additional storage device.

Computing device 1200 may include another input device 1211 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1200 may include a security interface device 1212. Security interface device 1212 may include any device that provides security measures for computing device 1200 such as intrusion detection, biometric validation, security encode or decode, managing access lists, malware detection, or spyware detection.

Computing device 1200, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

In first examples, an apparatus comprises an integrated circuit (IC) die structure comprising a device layer, and a metallization level over the device layer. The metallization level comprises one or more bonding regions further comprising metal features and an inorganic dielectric material. The metallization level comprises an inner region either surrounded by the bonding regions, or between an adjacent pair of the bonding regions. The inner region comprises a material with a composition of at least ten atomic percent carbon or at least ten atomic percent fluorine.

In second examples, for any of the first examples the bonding regions are first bonding regions, the metallization level is a first metallization level, the metal features are first metal features, the inner region is a first intervening region, and the apparatus further comprises a substrate structure comprising a second metallization level. The second metallization level comprises one or more second bonding regions further comprising substantially co-planar second metal features and an inorganic dielectric material, wherein the second metal features are in contact with at least a portion of corresponding ones of the first metal features, and a second inner region either surrounded by the second bonding regions, or between an adjacent pair of the second bonding regions, wherein the second inner region comprises a material with a composition of at least ten atomic percent carbon or at least ten atomic percent fluorine.

In third examples, for any of the first through second examples the substrate structure comprises one or more solder features on a side opposite the IC die structure.

In fourth examples, for any of the first through fourth examples the metallization level comprises at least four of the bonding regions, each of the bonding regions occupying one quadrant of the IC die structure and the inner region extending contiguously between each of the bonding regions.

In fifth examples, for any of the first through fourth examples the metallization level comprises a contiguous bonding region. The inner region is one of a plurality of inner regions, each of the plurality of inner regions surrounded by the contiguous bonding region.

In sixth examples, for any of the first through fifth examples the metallization level comprises one or more outer regions outside of the bonding regions. The outer regions comprise the material with the composition of at least ten atomic percent carbon or at least ten atomic percent fluorine.

In seventh examples, for any of the sixth examples, the outer regions comprise a single outer region substantially surrounding the bonding regions and the single outer region is contiguous with the inner region.

In eighth examples, for any of the sixth through seventh examples the bonding regions have at least two orthogonal edges within a plane of the metallization level and wherein the outer regions comprise a plurality of outer regions, at least one of the outer regions adjacent to each of the at least two orthogonal edges.

In ninth examples, for any of the first through eighth examples the IC die structure has at least two orthogonal edge sidewalls, wherein the two orthogonal edge sidewalls are both intersected by a third edge sidewall, and wherein the third edge sidewall intersects the bonding regions.

In tenth examples, for any of the first through ninth examples, the metallization level comprises one or more outer regions outside of the bonding regions. The outer regions comprise the material with the composition of at least ten atomic percent carbon or at least ten atomic percent fluorine, and the third edge sidewall intersects at least one of the outer regions.

In eleventh examples, an apparatus comprises an integrated circuit (IC) die structure comprising a device layer, and a first metallization level over the device layer. The first metallization level comprises one or more first bonding regions further comprising substantially co-planar first metal features and an inorganic dielectric material. The apparatus comprises a substrate structure comprising a second metallization level. The second metallization level comprises one or more second bonding regions further comprising substantially co-planar second metal features and an inorganic dielectric material. The second metal features are in contact with at least a portion of corresponding ones of the first metal features. At least one of the first or second metallization levels comprise an inner region either surrounded by the first or second bonding regions, or between an adjacent pair of the first or second bonding regions and the inner region comprises a hydrophobic structure.

In twelfth examples, for any of the eleventh examples, the first metallization level comprises a first inner region either surrounded by the first bonding regions, or between an adjacent pair of the first bonding regions, and the second metallization level comprises a second inner region either surrounded by the second bonding regions, or between an adjacent pair of the second bonding regions.

In thirteenth examples, for any of the eleventh through twelfth examples a side of the substrate structure opposite the IC die structure comprises one or more solder features.

In fourteenth examples, for any of the eleventh through thirteenth examples at least one of the first or second metallization levels comprises at least four bonding regions, each of the four bonding regions occupying one quadrant of the metallization levels, and the inner region extending contiguously between each of the four bonding regions.

In fifteenth examples, for any of the eleventh through fourteenth examples at least one of the metallization levels comprises a contiguous bonding region, and the inner region is one of a plurality of inner regions, each of the plurality of inner regions surrounded by the contiguous bonding region.

In sixteenth examples, for any of the eleventh through fifteenth examples at least one of the first or second metallization levels comprises one or more outer regions outside of the bonding regions, and wherein the outer regions comprise a hydrophobic structure.

In seventeenth examples, a method comprises receiving an integrated circuit (IC) die structure. A surface of the IC die structure comprises one or more first bonding regions. The method comprises receiving a substrate structure, wherein a surface of the substrate structure comprises one or more second bonding regions. The method comprises forming a plurality of liquid droplets on each of the first bonding regions or on each of the second bonding regions; and bonding the first bonding regions to the second bonding regions after the liquid droplets are gone.

In eighteenth examples, for any of the sixteenth through seventeenth examples each of the first bonding regions comprise substantially co-planar first metal features and an inorganic dielectric material, each of the second bonding regions comprising substantially co-planar second metal features and an inorganic dielectric material, and the surface of at least one of the IC die structure or the substrate structure comprises an inner region either surrounded by the first or second bonding regions, or located between an adjacent pair of the first or second bonding regions.

In nineteenth examples, for any of the eighteenth examples the method comprises aligning the IC die structure to the substrate structure based on a wettability contrast between the inner region and the first or second bonding regions.

In twentieth examples, for any of the nineteenth examples the surface of the IC die structure comprises a first inner region surrounded by contiguous first bonding regions, or located between an adjacent pair of first bonding regions. The surface of the substrate structure comprises a second inner region surrounded by contiguous second bonding regions or located between an adjacent pair of second bonding regions.

It will be recognized that principles of the disclosure are not limited to the embodiments so described, but instead can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
an integrated circuit (IC) die structure comprising a device layer, and a metallization level over the device layer, wherein the metallization level comprises:
one or more bonding regions further comprising metal features and an inorganic dielectric material; and
an inner region either surrounded by the bonding regions, or between an adjacent pair of the bonding regions, wherein the inner region comprises a material with a composition of at least ten atomic percent carbon or at least ten atomic percent fluorine.

2. The apparatus of claim 1, wherein:
the bonding regions are first bonding regions;
the metallization level is a first metallization level;
the metal features are first metal features;
the inner region is a first intervening region; and
the apparatus further comprises a substrate structure comprising a second metallization level,
wherein the second metallization level comprises:
one or more second bonding regions further comprising substantially co-planar second metal features and an inorganic dielectric material, wherein the second metal features are in contact with at least a portion of corresponding ones of the first metal features; and
a second inner region either surrounded by the second bonding regions, or between an adjacent pair of the second bonding regions, wherein the second inner region comprises a material with a composition of at least ten atomic percent carbon or at least ten atomic percent fluorine.

3. The apparatus of claim 2, wherein the substrate structure comprises one or more solder features on a side opposite the IC die structure.

4. The apparatus of claim 1, wherein the metallization level comprises at least four of the bonding regions, each of the bonding regions occupying one quadrant of the IC die structure and the inner region extending contiguously between each of the bonding regions.

5. The apparatus of claim 1, wherein the metallization level comprises a contiguous bonding region, and wherein the inner region is one of a plurality of inner regions, each of the plurality of inner regions surrounded by the contiguous bonding region.

6. The apparatus of claim 1, wherein the metallization level comprises one or more outer regions outside of the bonding regions, and wherein the outer regions comprise the material with the composition of at least ten atomic percent carbon or at least ten atomic percent fluorine.

7. The apparatus of claim 6, wherein the outer regions comprise a single outer region substantially surrounding the bonding regions, and wherein the single outer region is contiguous with the inner region.

8. The apparatus of claim 6, wherein the bonding regions have at least two orthogonal edges within a plane of the metallization level and wherein the outer regions comprise a plurality of outer regions, at least one of the outer regions adjacent to each of the at least two orthogonal edges.

9. The apparatus of claim 1, wherein the IC die structure has at least two orthogonal edge sidewalls, wherein the two orthogonal edge sidewalls are both intersected by a third edge sidewall, and wherein the third edge sidewall intersects the bonding regions.

10. The apparatus of claim 9, wherein;
the metallization level comprises one or more outer regions outside of the bonding regions;
the outer regions comprise the material with the composition of at least ten atomic percent carbon or at least ten atomic percent fluorine; and
the third edge sidewall intersects at least one of the outer regions.

11. An apparatus comprising:
an integrated circuit (IC) die structure comprising a device layer, and a first metallization level over the device layer, wherein the first metallization level comprises one or more first bonding regions further comprising substantially co-planar first metal features and an inorganic dielectric material; and
a substrate structure comprising a second metallization level, wherein:
the second metallization level comprises one or more second bonding regions further comprising substantially co-planar second metal features and an inorganic dielectric material;
the second metal features are in contact with at least a portion of corresponding ones of the first metal features;
at least one of the first or second metallization levels comprise an inner region either surrounded by the first or second bonding regions, or between an adjacent pair of the first or second bonding regions; and
the inner region comprises a hydrophobic structure.

12. The apparatus of claim 11, wherein:
the first metallization level comprises a first inner region either surrounded by the first bonding regions, or between an adjacent pair of the first bonding regions; and
the second metallization level comprises a second inner region either surrounded by the second bonding regions, or between an adjacent pair of the second bonding regions.

13. The apparatus of claim 11, wherein a side of the substrate structure opposite the IC die structure comprises one or more solder features.

14. The apparatus of claim 11, wherein at least one of the first or second metallization levels comprises at least four bonding regions, each of the four bonding regions occupying one quadrant of the metallization levels, and the inner region extending contiguously between each of the four bonding regions.

15. The apparatus of claim 11, wherein at least one of the metallization levels comprises a contiguous bonding region, and wherein the inner region is one of a plurality of inner regions, each of the plurality of inner regions surrounded by the contiguous bonding region.

16. The apparatus of claim 11, wherein at least one of the first or second metallization levels comprises one or more outer regions outside of the bonding regions, and wherein the outer regions comprise a hydrophobic structure.

17. A method, comprising:
receiving an integrated circuit (IC) die structure, wherein a surface of the IC die structure comprises one or more first bonding regions;
receiving a substrate structure, wherein a surface of the substrate structure comprises one or more second bonding regions;
forming a plurality of liquid droplets on each of the first bonding regions or on each of the second bonding regions; and
bonding the first bonding regions to the second bonding regions after the liquid droplets are gone.

18. The method of claim 17, wherein:
each of the first bonding regions comprise substantially co-planar first metal features and an inorganic dielectric material;
each of the second bonding regions comprising substantially co-planar second metal features and an inorganic dielectric material; and
the surface of at least one of the IC die structure or the substrate structure comprises an inner region either surrounded by the first or second bonding regions, or located between an adjacent pair of the first or second bonding regions.

19. The method of claim 18, further comprising aligning the IC die structure to the substrate structure based on a wettability contrast between the inner region and the first or second bonding regions.

20. The method of claim 19, wherein:
the surface of the IC die structure comprises a first inner region surrounded by contiguous first bonding regions, or located between an adjacent pair of first bonding regions; and
the surface of the substrate structure comprises a second inner region surrounded by contiguous second bonding regions or located between an adjacent pair of second bonding regions.
